(19) United States
(12) Patent Application Publication
(10) Pub. No.: US 2026/0143602 A1
(43) Pub. Date: May 21, 2026

(54) DISPLAY DEVICE AND ELECTRONIC DEVICE

(71) Applicant: SAMSUNG ELECTRONICS CO., LTD., Suwon-si (KR)

(72) Inventor: Jeongheon KIM, Suwon-si (KR)

(73) Assignee: SAMSUNG ELECTRONICS CO., LTD., Suwon-si (KR)

(21) Appl. No.: 19/406,280

(22) Filed: Dec. 2, 2025

Related U.S. Application Data
(63) Continuation of application No. PCT/KR2025/013876, filed on Sep. 8, 2025.

(30) Foreign Application Priority Data
Nov. 21, 2024 (KR) 10-2024-0167540

(51) Int. Cl. H05K 5/02

(52) U.S. Cl. CPC H05K 5/0217

(57) ABSTRACT

A display device may include: a display panel; a chassis covering at least one side of the display panel, the chassis including a board mounting portion; and a printed circuit board including: a coupling portion couplable to the board mounting portion, and a grounding portion protruding from a surface of the coupling portion, wherein the printed circuit board and the chassis are configured such that, with the coupling portion coupled to the board mounting portion, the grounding portion is in contact with the board mounting portion so as to ground the printed circuit board to the chassis, and the printed circuit board is mounted to the chassis.

### [CROSS-REFERENCE TO RELATED APPLICATIONS]

This is a continuation application, under 35 U.S.C. §111(a), of International Application No. PCT/ KR2025/013876, filed September 8, 2025, which claims priority under 35 U.S.C. §119 to Korean Patent Application No. 10-2024-0167540, filed November 21, 2024, in the Korean Intellectual Property Office, the disclosures of which are incorporated herein in their entireties by reference.

### [TECHNICAL FIELD]

The disclosure relates to a display device and an electronic device including a printed circuit board.

### [BACKGROUND ART]

A display device is an electronic device configured to convert acquired or stored electrical information to visual information and display the visual information to a user, and is used in various areas, such as a home, a business, and the like.

For example, the display device may include a monitor device connected to a personal computer or a server computer, a portable computer device, a navigation terminal device, a general television device, an Internet Protocol television (IPTV) device, a portable terminal device, such as a smart phone, a tablet PC, a personal digital assistant (PDA) or a cellular phone, various display devices used to reproduce images, such as advertisements, or various kinds of audio/video systems.

As an example, the display device may include a display panel and a bottom chassis that accommodates the display panel, and various printed circuit boards for controlling the operation of the display device may be installed on the rear surface of the bottom chassis. During the operation of the printed circuit boards, electromagnetic noise may be generated from the printed circuit boards, and in order to avoid accumulation of such electromagnetic noise, the printed circuit boards need to be grounded to the bottom chassis.

### [DISCLOSURE]

### [Technical Problem]

One aspect of the disclosure provides a display device and an electronic device with improved electromagnetic susceptibility (EMS).

One aspect of the disclosure provides a display device and an electronic device capable of reducing electromagnetic interference (EMI).

The technical objectives of the disclosure are not limited to the above, and other objectives that are not described above will be clearly understood by those skilled in the art from the above detailed description.

### [Technical Solution]

In accordance with the present disclosure, a display device may include: a display panel; a chassis covering at least one side of the display panel, the chassis including a board mounting portion; and a printed circuit board including: a coupling portion couplable to the board mounting portion, and a grounding portion protruding from a surface of the coupling portion, wherein the printed circuit board and the chassis are configured such that, with the coupling portion coupled to the board mounting portion, the grounding portion is in contact with the board mounting portion so as to ground the printed circuit board to the chassis, and the printed circuit board is mounted to the chassis.

The grounding portion may include a material configured such that, with the coupling portion coupled to the board mounting portion, the board mounting portion presses and thereby deforms the material.

The board mounting portion may include a pressing portion configured such that, with the coupling portion coupled to the board mounting portion, the pressing portion presses and thereby deforms the material.

The grounding portion may include: a first protrusion, and a second protrusion spaced apart from the first protrusion in a direction of an edge of the printed circuit board, and having a size larger than the first protrusion, and the grounding portion and the board mounting portion may be configured such that, as the coupling portion is coupled to the board mounting portion, the pressing portion presses the second protrusion then presses the first protrusion.

The board mounting portion may include: a first end including the pressing portion, and a second end opposite to the first end, the second end may protrude from a rear surface of the chassis, and the first end may be closer to the rear surface of the chassis than the second end, and may be configured such that, with the coupling portion coupled to the board mounting portion, the printed circuit board may be pressed toward the chassis by the first end.

The board mounting portion may include a mounting guide extending from the pressing portion in a direction away from a rear surface of the chassis, and the mounting guide may be configured such that, as the coupling portion may be coupled to the board mounting portion, movement of the coupling portion may be guided by the mounting guide.

The grounding portion may include: a first protrusion, and a second protrusion spaced apart from the first protrusion, and a size of the first protrusion may be equal to a size of the second protrusion.

The grounding portion may include a plurality of protrusions arranged in a grid pattern.

The grounding portion may include a material that may be more flexible than a material of the board mounting portion.

The grounding portion may include lead.

The grounding portion may be soldered to the coupling portion.

The printed circuit board may include: a passing portion through which the board mounting portion may be passable, and a mounting space between the board mounting portion and a back surface of the chassis and into which at least a portion of the coupling portion may be accommodatable, and the chassis and the printed circuit board may be configured such that, with the board mounting portion passed through the passing portion and the printed circuit board slid relative to the chassis toward the board mounting portion, the portion of the coupling portion may be accommodated in a mounting space.

The board mounting portion may include a portion that may be open in a direction in which the printed circuit board extends.

The display panel may be on a first side of the chassis, and the printed circuit board may be on a second side of the chassis opposite to the first side.

In accordance with the present disclosure, an electronic device may include: a chassis including a board mounting portion; and a printed circuit board including: a coupling portion couplable to the board mounting portion, and a grounding portion protruding from a surface of the coupling portion and including a deformable material, wherein the printed circuit board and the board mounting portion are configured such that, with the coupling portion coupled to the board mounting portion, the deformable material is pressed and thereby deformed by the board mounted portion, the board mounting portion contacts the deformable material so as to ground the printed circuit board to the chassis, and the printed circuit board is mounted to the chassis.

### [DESCRIPTION OF DRAWINGS]

FIG. 1 illustrates a display device according to an embodiment of the disclosure.

FIG. 2 illustrates an exploded view of a display device according to an embodiment of the disclosure.

FIG. 3 illustrates an enlarged cross sectional view of a portion of a display panel of a display device according to an embodiment of the disclosure.

FIG. 4 illustrates a printed circuit board mounted to the rear side of a bottom chassis of a display device according to an embodiment of the disclosure.

FIG. 5 illustrates an enlarged view of portion A shown in FIG. 4.

FIG. 6 illustrates an enlarged view of portion B shown in FIG. 5.

FIG. 7 illustrates a state before a printed circuit board is mounted to a bottom chassis of a display device according to an embodiment of the disclosure.

FIG. 8 illustrates an enlarged view of portion C shown in FIG. 7.

FIG. 9 illustrates a cross-sectional view taken along line D-D' of FIG. 6.

FIG. 10 illustrates a cross-sectional view taken along line E-E' of FIG. 8.

FIG. 11 illustrates an enlarged view of deformation of a grounding portion while a printed circuit board is being mounted to a bottom chassis of a display device according to an embodiment of the disclosure.

FIG. 12 illustrates a state in which a solder paste is applied to a printed circuit board of a display device according to an embodiment of the disclosure.

FIG. 13 illustrates an enlarged cross sectional view of a portion of a display device before a printed circuit board is mounted to a bottom chassis according to an embodiment of the disclosure.

FIG. 14 illustrates an enlarged cross sectional view of a portion of a display device after a printed circuit board is mounted to a bottom chassis according to an embodiment of the disclosure.

FIG. 15 illustrates a state in which a solder paste is applied to a printed circuit board of a display device according to an embodiment of the disclosure.

### [MODE FOR INVENTION]

Various embodiments of the document and terms used therein are not intended to limit the technical features described in this document to specific embodiments, and should be understood to include various modifications, equivalents, or substitutes of the corresponding embodiments.

In connection with the description of the drawings, similar reference numerals may be used for similar or related components.

The singular form of a noun corresponding to an item may include one or a plurality of the items unless clearly indicated otherwise in a related context.

In this document, phrases, such as “A or B”, “at least one of A and B”, “at least one of A or B,” “A, B or C,” “at least one of A, B and C,” and “at least one of A, B, or C”, may include any one or all possible combinations of items listed together in the corresponding phrase among the phrases.

The terms of “~part”, “~module” and “~member” may be implemented in hardware or software. In some embodiments, a plurality of “~parts”, “~modules” and “~members” may be implemented as a single component. In some embodiments, a single “~part”, “~module” and “~member” may include plurality of a plurality of components.

The terms used herein are for the purpose of describing the embodiments and are not intended to restrict and/or to limit the disclosure. The singular expressions herein may include plural expressions, unless the context clearly dictates otherwise. In addition, the terms “comprises”, “includes”, and “has” are intended to indicate that there are features, numbers, steps, operations, elements, parts, or combinations thereof described in the disclosure, and do not exclude the presence or addition of one or more other features, numbers, steps, operations, elements, parts, or combinations thereof.

It will be understood that, although the terms first, second, etc. used in the disclosure may be used herein to describe various components, these components should not be limited by these terms. These terms are only used to distinguish one component from another. For example, a first element could be termed a second element, and similarly, a second element could be termed a first element without departing from the scope of the disclosure. The term “and/or” includes combinations of one or all of a plurality of associated listed items.

When one (e.g., a first) element is referred to as being “coupled” or “connected” to another (e.g., a second) element with or without the term “functionally” or “communicatively,” it means that the one element is connected to the other element directly, wirelessly, or via a third element.

It is to be understood that if a certain component is referred to as being "coupled with," "coupled to," "supported on" or "in contact with" another component, it means that the component may be coupled with the other component directly or indirectly via a third component.

It will also be understood that when a component is referred to as being “on” another component, it may be directly on the other component or intervening components may also be present.

Meanwhile, the terms "up-down direction," "front-rear direction," etc. used in the following description are defined based on the drawings, and the shape and position of each component are not limited by these terms. For example, the terms "front" and "rear" below may be defined based on the X direction shown in the drawings, respectively. The terms "upward" and "downward" below may be defined based on the Z direction shown in the drawings, respectively. The terms "left direction" and "right direction" below may be defined based on the Y direction shown in the drawings. The term "vertical direction" below may mean the Z direction shown in the drawings, and the term "horizontal direction" below may mean the X direction or Y direction shown in the drawings, respectively.

In describing various embodiments of the disclosure below, a display device, which is one type of electronic device, has been described as an example for convenience, but the concept of the disclosure is not limited thereto. The concept of the disclosure is applicable to various electronic devices including printed circuit boards.

Hereinafter, embodiments of the invention will be described in detail with reference to the accompanying drawings.

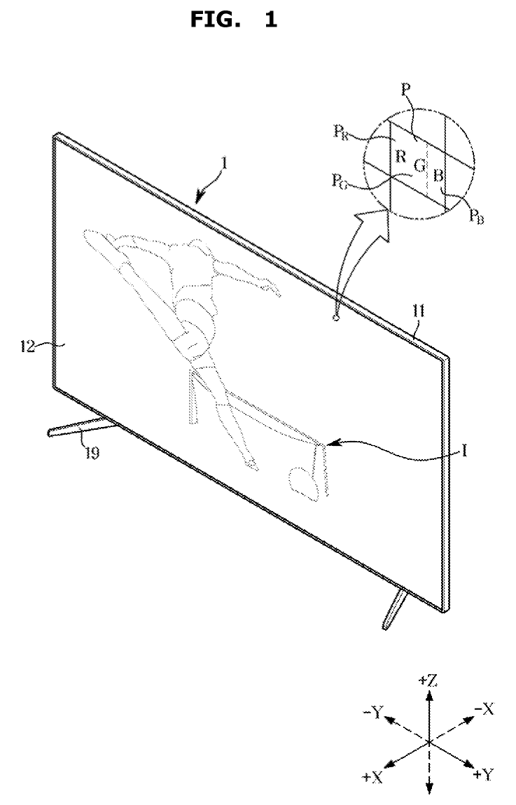

FIG. 1 illustrates a display device according to an embodiment of the disclosure.

A display device 1 is a device that may process an image signal received from the outside and visually display the processed image. Hereinafter, a case in which the display device 1 is a television (TV) is exemplified, but the disclosure is not limited thereto. For example, the display device 1 may be implemented in various forms, such as a monitor, a portable multimedia device, and a portable communication device, and the display device 1 is not limited in its form as long as the display device visually displays an image.

In addition, the display device 1 may be a large format display (LFD) installed outdoors, such as on a roof of a building or at a bus stop. Here, the outdoors is not necessarily limited to the outdoors, and the display device 1 according to an embodiment may be installed wherever a large number of people may enter and exit, even indoors, such as at subway stations, shopping malls, movie theaters, companies, and stores.

In FIG. 1, the display device 1 is illustrated as a flat display device having a planar screen by way of example, but the disclosure is not limited thereto. The display device according to the concept of the disclosure may also be applied to a curved display device or a variable-type (bendable or flexible) display device in which the state may be varied between a flat state and a curved state. In addition, the configuration of the disclosure may be applied to display devices of various shapes regardless of the screen size or aspect ratio of the display device.

The display device 1 may receive content data including video signals and audio signals from various content sources, and output video and audio corresponding to the video signals and the audio signals. For example, the display device 1 may receive content data through a broadcast reception antenna or a wired cable, receive content data from a content reproduction device, or receive content data from a content providing server of a content provider.

The display device 1 may display an image corresponding to video data and output sound corresponding to audio data. For example, the display device 1 may reconstruct a plurality of image frames included in the video data and sequentially display the plurality of image frames. In addition, the display device 1 may reconstruct an audio signal included in the audio data and continuously output sounds according to the audio signals.

As shown in FIG. 1, the display device 1 includes a main body 11 and a screen 12 configured to display an image I.

The display device 1 may be installed in a standing manner on an indoor or outdoor floor surface or on furniture, or may be installed in a wall-mounted form on a wall surface or inside a wall. For example, the display device 1 may include a support leg 19 provided at a lower portion of the main body 11 to be installed in a standing manner on an indoor or outdoor floor surface or on furniture.

The main body 11 may form an external appearance of the display device 1, and components for performing various functions such as displaying an image by the display device 1 may be provided in the main body 11.

The display device 1 may be configured to display an image I. Specifically, the screen 12 may be formed on a front surface of the main body 11, and the display device 1 may display the image I through the screen 12. For example, the screen 12 may display a still image or a video. Further, the screen 12 may display a two-dimensional flat image or a three-dimensional stereoscopic image using the parallax of a user's eyes.

A plurality of pixels P may be formed on the screen 12, and the image I displayed on the screen 12 may be formed by light emitted from each of the plurality of pixels P. For example, the image I may be formed on the screen 12 by combining the light emitted by the plurality of pixels P like a mosaic.

Each of the plurality of pixels P may emit light of various brightnesses and colors. Specifically, each of the plurality of pixels P may include sub-pixels PR, PG, and PB. The sub-pixels PR, PG, and PB may include a red sub-pixel PR capable of emitting red light, a green sub-pixel PG capable of emitting green light, and a blue sub-pixel PB capable of emitting blue light. For example, the red light may re light having a wavelength of approximately 620 nm (nanometers, one billionth of a meter) to 750 nm, the green light may re light having a wavelength of approximately 495 nm to 570 nm, and the blue light may re light having a wavelength of approximately 450 nm to 495 nm.

By combining the red light of the red sub-pixel PR, the green light of the green sub-pixel PG, and the blue light of the blue sub-pixel PB, each of the plurality of pixels P may emit light of various brightness and various colors.

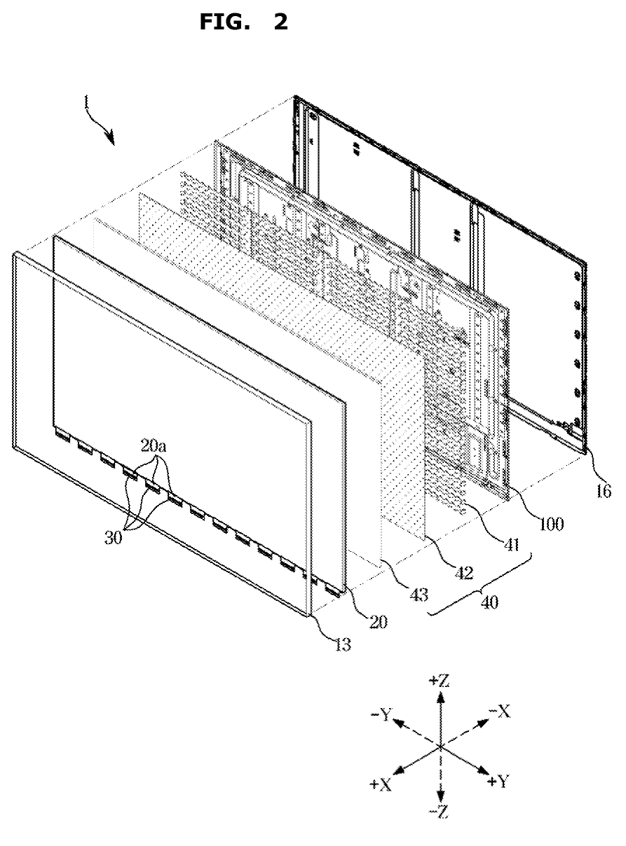

FIG. 2 is an exploded view of a display device according to an embodiment of the disclosure.

Referring to FIG. 2, various components for generating an image I on the screen 12 may be provided inside the main body 11 of the display device 1 according to an embodiment of the disclosure.

For example, the display device 1 may include a display panel 20. The display panel 20 may be provided in the main body 11. The display panel 20 may be provided to display the image I. The screen 12 described in FIG. 1 may be formed on the front surface of the display panel 20.

As an example, the display panel 20 may have a substantially rectangular shape. Specifically, the display panel 20 may have a shape in which the length of a width side and the length of a longitudinal side are different from each other. That is, the display panel 20 may be provided to have a long side and a short side. The display panel 20 may be provided in the shape of a rectangular plate. However, the disclosure is not limited thereto, and the display panel 20 may be provided in the shape of a square plate in which the lengths of the long side and the short side are almost the same.

The display panel 20 may be provided in various sizes. The ratio of the long side and the short side of the display panel 20 is not limited to general cases, such as 16:9 and 4:3, but may instead be provided in an arbitrary ratio.

In an embodiment of the disclosure, the display panel 20 of the display device 1 may be configured with a non-emissive display type panel, such as a liquid crystal display (LCD).

On one side of the display panel 20, a cable 20a for transmitting image data to the display panel 20 and a display driver integrated circuit (DDI) 30 (hereinafter referred to as “driver IC”) for processing digital image data and outputting an analog image signal may be provided.

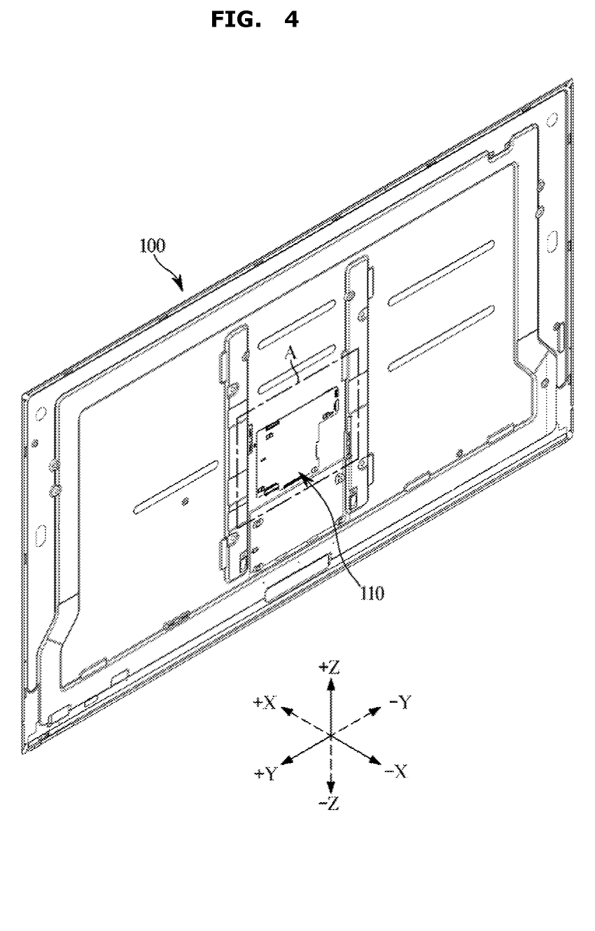

The cable 20a may electrically connect a control assembly/power assembly of a printed circuit board (PCB, 110, see FIG. 4) and the driver IC 30, and may also electrically connect the driver IC 30 and the display panel 20. The cable 20a may include a flexible flat cable or a film cable that may be bent.

The driver IC 30 receives image data and power from the control assembly/power assembly of the printed circuit board 110 through the cable 20a, and may transmit image data and driving current to the display panel 20 through the cable 20a.

In addition, the cable 20a and the driver IC 30 may be implemented integrally as a film cable, a chip on film (COF), a tape carrier packet (TCP), or the like. In other words, the driver IC 30 may be disposed on the cable 20a. However, the disclosure is not limited thereto, and the driver IC 30 may be disposed on the display panel 20.

A detailed description of the structure of the display panel 20 will be given below.

The display device 1 may include a backlight Unit 40 provided to emit light toward the display panel 20. The backlight unit 40 may be provided in the main body 11. The backlight unit 40 may be disposed at the rear of the display panel 20 and may be provided to emit light toward the front in which the display panel 20 is located. Specifically, the backlight unit 40 may be configured as a surface light source. The display panel 20 may block or transmit the light emitted from the backlight unit 40.

The backlight unit 100 may include a point light source that emits monochromatic light or white light, and may be configured to refract, reflect, and scatter the light to convert the light emitted from the point light source into a uniform surface light. The backlight unit 40 may emit uniform surface light toward the front by refracting, reflecting, and scattering light emitted from a point light source.”

As shown in FIG. 2, the backlight unit 40 may include a light source module 41. The light source module 41 may generate and emit light. Specifically, the light source module 41 may be provided to emit monochromatic light or white light.

The light source module 41 may include a plurality of light sources provided to emit light and a light source substrate on which the plurality of light sources are mounted.

As shown in FIG. 2, the backlight unit 40 may include a reflective sheet 42 provided to reflect light. The reflective sheet 42 may reflect light toward the front or in a direction approximate to the front.

As one example, the reflective sheet 42 may be attached to a front surface of the light source module 41. The reflective sheet 42 may be provided in front of the light source module 41.

For example, the light source module 41 may emit light in various directions in front of the reflective sheet 42. The light emitted from the light source module 41 may be emitted not only toward an optical member 43 (e.g., a diffusion plate) to be described below, but may also be emitted toward the reflective sheet 42, and the reflective sheet 42 may reflect the light emitted toward the reflective sheet 42 toward the optical member 43 (e.g., a diffusion plate).

Alternatively, the light emitted from the light source module 41 may pass through various objects, such as the optical member 43 (e.g., the diffusion plate and/or the optical sheet), and a portion of the light may be reflected at the surface of the optical member 43(e.g., the diffusion plate and/or the optical sheet). The reflective sheet 42 may reflect the light, which has been reflected in this manner, back to the front.

As one example, the backlight unit 40 may include an optical member 43. For example, the optical member 43 may include at least one of a diffusion plate and an optical sheet. The optical member 43 may be provided in front of the reflective sheet 42.

For example, the optical member 43 may include a diffuser plate provided to uniformly diffuse light. The diffuser plate may be provided in front of the light source module 41 and the reflective sheet 42. The diffuser plate may uniformly diffuse the light emitted from the light source module 41 and then emit the light to the front.

For example, the optical member 43 may include an optical sheet provided to further improve the luminance and luminance uniformity of the emitted light. The optical sheet may be provided to refract and scatter the light emitted from the front surface of the diffusion plate. For example, the optical sheet may include various types of sheets, such as a diffusion sheet, a prism sheet, a reflective polarizing sheet, and a quantum dot sheet.

The display device 1 may include a display case provided to support the various components of the main body 11 of the display device 1. In other words, the various components of the main body 11 may be accommodated inside the display case. The display case may form the external appearance of the display device 1.

As an example, the display case may support the display panel 20. As an example, the display case may support the backlight unit 40. As an example, the display case may support the printed circuit board 110.

As an example, the display device 1 may include a top chassis 13. The top chassis 13 may include a top chassis 13 that supports a front surface or a side surface of the display panel 20. As an example, the top chassis 13 may be provided in the shape of a substantially rectangular frame.

The top chassis 13 may form a bezel that is disposed to face the front of the display device 1 and supports the front surface of the display panel 20. However, when the display device 1 is a bezel-less type display device with a very narrow or no bezel, the top chassis 13 may be provided to support only the side surfaces of the display panel 20. Alternatively, when the bottom chassis 100 supports the side surfaces of the display panel 20, the display device 1 may not include the top chassis 13.

As one example, the display device 1 may include a bottom chassis 100. The bottom chassis 100 may cover the rear of the display panel 20. The bottom chassis 100 may be coupled to the rear of the top chassis 13. The bottom chassis 100 may support various components of the display device 1, such as the backlight unit 40, the printed circuit board 110, and the like.

The bottom chassis 100 may be formed to have a substantially flat plate shape, but is not limited thereto. The bottom chassis 100 may be formed including a material with high thermal conductivity to dissipate heat generated from the light source module 41 to the outside. As an example, the bottom chassis 100 may be formed including a metal material, such as aluminum or stainless steel (SUS), or a plastic material, such as ABS.

As one example, the display device 1 may include a middle mold. The middle mold may be disposed between the top chassis 13 and the bottom chassis 100. For example, the middle mold may support at least some components of the backlight unit 40.

As one example, the display device 1 may include a rear cover 16. The rear cover 16 may be disposed at the rear of the bottom chassis 100 and may cover the bottom chassis 100 and various components (e.g., the printed circuit board 110, etc.) mounted to the rear of the bottom chassis 100.

Meanwhile, unlike the example shown in FIG. 2, the display case of the display device 1 according to the spirit of the disclosure may not include some components among the top chassis, middle mold, bottom chassis, and rear cover.

The configuration of the display device 1 described with reference to FIG. 2 above is only one example for describing a display device according to the spirit of the disclosure, and the spirit of the disclosure is not limited thereto. The display device according to the spirit of the disclosure may be provided to include various configurations for performing the function of providing an image through a screen.

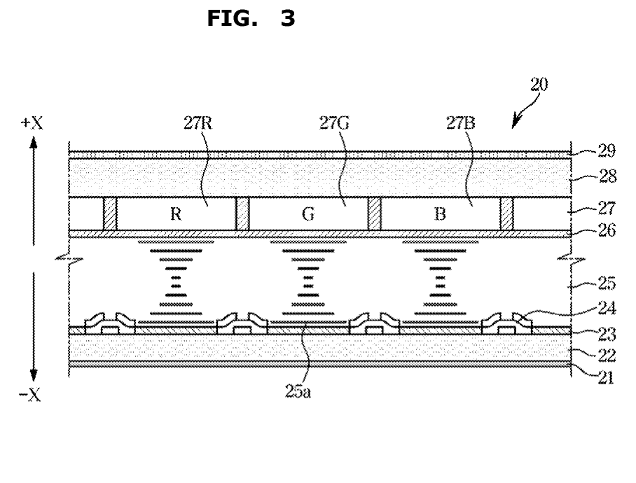

FIG. 3 illustrates an enlarged cross sectional view of a portion of a display panel of a display device according to an embodiment of the disclosure.

Referring to FIG. 3, the display panel 20 included in the display device 1 according to an embodiment of the disclosure may be configured as a liquid crystal display (LCD) panel, and may be provided to block or transmit light emitted from the backlight unit 40. By the operation in which the display panel 20 blocks or transmits the light emitted from the backlight unit 40, an image I may be formed in front of the display panel 20

A front surface of the display panel 20 may form the screen 12 of the display device 1 described above, and the display panel 20 may include a plurality of pixels P. The plurality of pixels P included in the display panel 20 may independently block or transmit the light emitted from the light source device 100, and the light transmitted by the plurality of pixels P may form the image I to be displayed on the screen 12.

For example, as shown in FIG. 3, the display panel 20 may include a first polarizing film 21, a first transparent substrate 22, a pixel electrode 23, a thin-film transistor (TFT) 24, a liquid crystal layer 25, a common electrode 26, a color filter 27, a second transparent substrate 28, and a second polarizing film 29.

The first transparent substrate 22 and the second transparent substrate 28 may fixedly support the pixel electrode 23, the thin-film transistor 24, the liquid crystal layer 25, the common electrode 26, and the color filter 27. The first and second transparent substrates 22 and 28 may be formed of tempered glass or transparent resin.

The first polarizing film 21 and the second polarizing film 29 may be provided on outer sides of the first and second transparent substrates 22 and 28, respectively.

The first polarizing film 21 and the second polarizing film 29 may transmit specific polarized light and block the other polarized light, respectively. For example, the first polarizing film 21 may transmit light polarized in a first direction and block the other polarized light. In addition, the second polarizing film 29 may transmit light polarized in a second direction and block the other polarized light. In this case, the first direction and the second direction may be perpendicular to each other. Accordingly, the polarization direction of the light transmitted through the first polarizing film 21 and the vibration direction of the light transmitted through the second polarizing film 29 may be perpendicular to each other. As a result, light generally cannot simultaneously pass through both the first polarizing film 21 and the second polarizing film.

A color filter 27 may be provided on the inner side of the second transparent substrate 28.

The color filter 27 may include a red filter 27R configured to transmit red light, a green filter 27G configured to transmit green light, and a blue filter 27B configured to transmit blue light. In addition, the red filter 27R, the green filter 27G, and the blue filter 27B may be disposed parallel to each other. A region in which the color filter 27 is formed may correspond to the pixel P described above. A region in which the red filter 27R is formed may correspond to the red sub-pixel PR, a region in which the green filter 27G is formed may correspond to the green sub-pixel PG, and a region in which the blue filter 27B is formed may correspond to the blue sub-pixel PB.

The pixel electrode 23 may be provided on an inner side of the first transparent substrate 22, and the common electrode 26 may be provided on the inner side of the second transparent substrate 28.

The pixel electrode 23 and the common electrode 26 may be formed of a metal material through which electricity is conducted and may generate an electric field for changing the arrangement of liquid crystal molecules 25a constituting the liquid crystal layer 25 to be described below.

The pixel electrode 23 and the common electrode 26 may be composed of a transparent material, and may allow light incident from the outside to pass therethrough. For example, the pixel electrode 23 and the common electrode 26 may be composed of indium tin oxide (ITO), indium zinc oxide (IZO), a silver nanowire (Ag nanowire), a carbon nanotube (CNT), graphene, poly3,4-ethylenedioxythiophene) (PEDOT), or the like. A thin film transistor (TFT) 24 may be provided on an inner side of the second transparent substrate 22.

The thin film transistor 24 may allow or block the current flowing to the pixel electrode 23. For example, by turning the thin-film transistor 24 on (closing) or off (opening), an electric field may be formed or removed from between the pixel electrode 23 and the common electrode 26.

The thin film transistor 24 may be composed of poly-silicon, and may be formed by semiconductor processes, such as a lithography process, a deposition process, an ion implantation process, and the like.

The liquid crystal layer 25 is formed between the pixel electrode 23 and the common electrode 26. The liquid crystal layer 25 is filled with liquid crystal molecules 25a.

Liquid crystals re an intermediate state between a solid (crystal) and a liquid. Most liquid crystal materials are organic compounds, and their molecular shape is a long and thin bar. The arrangement of the molecules may be irregular in one direction, but is regular in another direction to exhibit a crystalline form. As a result, the liquid crystal has both fluidity of a liquid and optical anisotropy of a crystal (solid).

Further, the liquid crystal may also exhibit optical properties depending on a change in the electric field. For example, in the liquid crystal, the direction of the arrangement of molecules constituting the liquid crystal may be changed according to the change in electric field. When an electric field is generated in the liquid crystal layer 25, the liquid crystal molecules 25a of the liquid crystal layer 25 are arranged according to the direction of the electric field, and when an electric field is not generated in the liquid crystal layer 25, the liquid crystal molecules 25a may be irregularly arranged or may be arranged along an alignment layer. As a result, the optical properties of the liquid crystal layer 25 may be changed according to the presence or absence of the electric field passing through the liquid crystal layer 25.

The structure of the display panel 20 described above with reference to FIG. 3 is merely one example of a structure that the display panel of the display device according to the concept of the disclosure may have, and the concept of the disclosure is not limited thereto

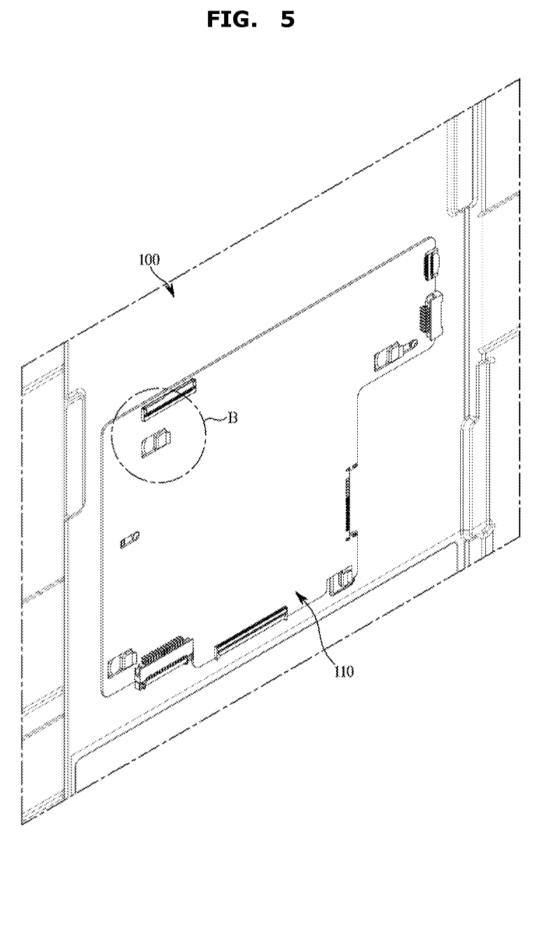

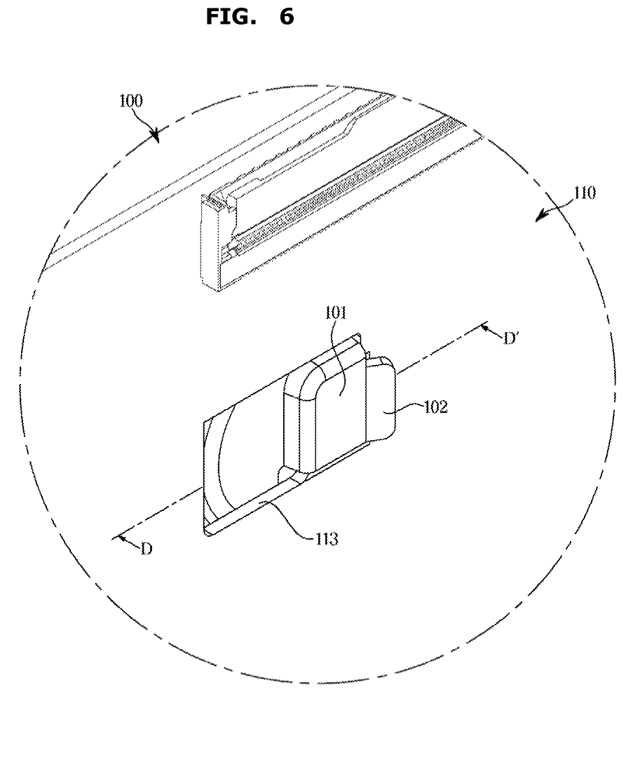

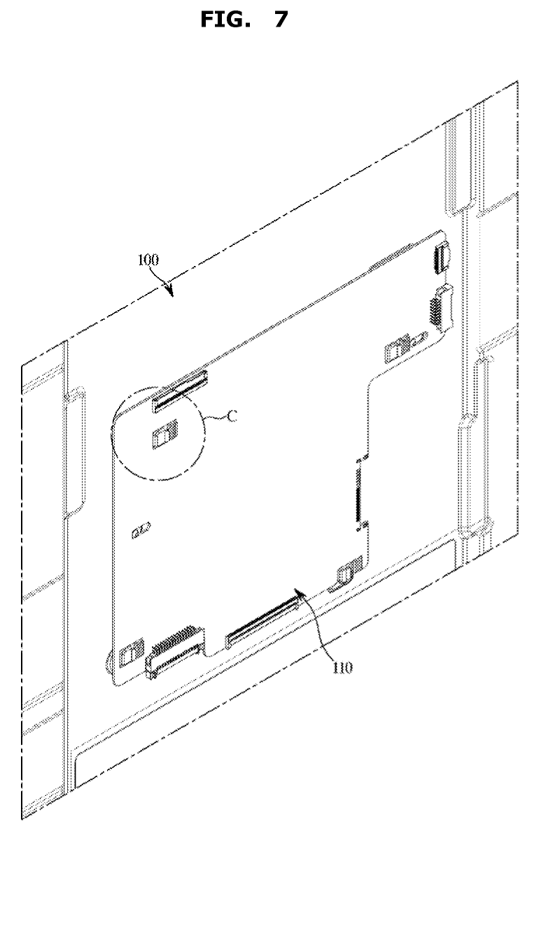

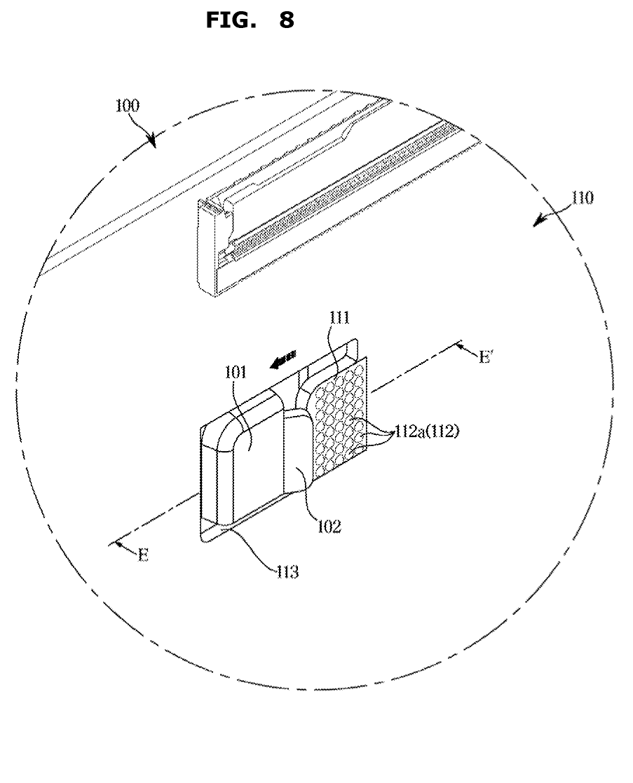

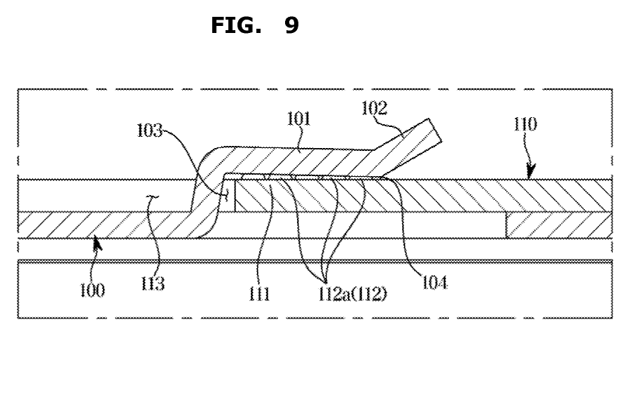

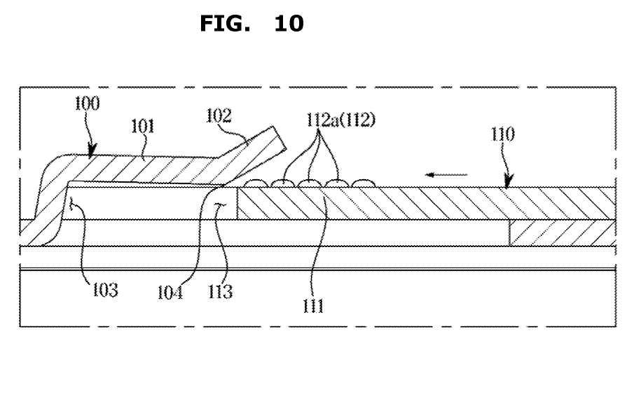

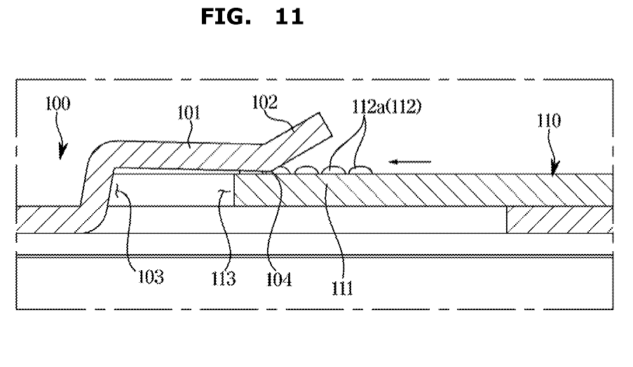

FIG. 4 illustrates a printed circuit board mounted to the rear side of a bottom chassis of a display device according to an embodiment of the disclosure. FIG. 5 illustrates an enlarged view of portion A shown in FIG. 4. FIG. 6 illustrates an enlarged view of portion B shown in FIG. 5. FIG. 7 illustrates a state before a printed circuit board is mounted to a bottom chassis of a display device according to an embodiment of the disclosure. FIG. 8 illustrates an enlarged view of portion C shown in FIG. 7. FIG. 9 illustrates a cross-sectional view taken along line D-D' of FIG. 6. FIG. 10 illustrates a cross-sectional view taken along line E-E' of FIG. 8. FIG. 11 illustrates an enlarged view of deformation of a grounding portion while a printed circuit board is being mounted to a bottom chassis of a display device according to an embodiment of the disclosure.

Referring to FIGS. 4 to 11, the display device 1 according to an embodiment of the disclosure may include a printed circuit board 110 for controlling the operation of the backlight unit 40 and the display panel 20. For example, the printed circuit board 110 may include a control assembly and a power assembly for supplying power to the backlight unit 40 and the display panel 20. The printed circuit board 110 may be disposed on a second side opposite to a first side of the bottom chassis 100 on which the display panel 20 is disposed.

As one example, the control assembly of the printed circuit board 110 may include a control circuit that controls the operation of the display panel 20 and the backlight unit 40. The control circuit processes image data received from an external content source, transmits the image data to the display panel 20, and may transmit dimming data to the backlight unit 40.

As one example, the power assembly of the printed circuit board 110 may supply power to the display panel 20 and the backlight unit 40 such that the backlight unit 40 outputs surface light and the display panel 20 blocks or transmits the light of the backlight unit 40.

The control assembly and the power assembly of the printed circuit board 110 may be implemented as various circuits. For example, the power circuit may include a power circuit board on which components, such as a capacitor, a coil, a resistor element, a processor and the like are mounted. In addition, the control circuit may include a control circuit board on which a memory, a processor, and the like are mounted.

In FIG. 4, for the sake of convenience of description, only a single printed circuit board 110 is illustrated as being mounted to the bottom chassis 100, but two or more printed circuit boards 110 may be mounted to the bottom chassis 100.

The printed circuit board 110 according to an embodiment of the disclosure may be detachably mounted to the bottom chassis 100. As an example, the printed circuit board 110 may be mounted to the bottom chassis 100 in a sliding manner. The printed circuit board 110 may be configured to be mounted to the bottom chassis 100 by moving in a direction, in which the printed circuit board 110 extends, while being aligned parallel to the bottom chassis 100 on the rear side of the bottom chassis 100. For example, the printed circuit board 100 may be mounted to or detached from the bottom chassis 100 by moving in a left-right direction with respect to the bottom chassis 100. The bottom chassis 100 and the printed circuit board 110 may be configured such that the printed circuit board 110 is mounted to the bottom chassis 100 without a fastening member, such as a screw.

The bottom chassis 100 may include a board mounting portion 101 on which the printed circuit board 110 may be mounted. The board mounting portion 101 may protrude from the rear surface of the bottom chassis 100. The board mounting portion 101 may be provided to fix at least a portion of the printed circuit board 110. The board mounting portion 101 may be provided such that at least a portion of the printed circuit board 110 is grounded thereto. The board mounting portion 101 may be coupled to the coupling portion 111 of the printed circuit board 110. The board mounting portion 101 may ground the coupling portion 111 of the printed circuit board 110. Although FIG. 5 illustrates four board mounting portions 101, the number of board mounting portions 101 is not limited thereto, and may be provided as three or fewer or five or more.

The board mounting portion 101 may include a pressing portion 104 provided to press and deform a grounding portion 112 of the printed circuit board 110 while the coupling portion 111 of the printed circuit board 110 is being coupled to the board mounting portion 101. The pressing portion 104 may be provided at one end of the board mounting portion 101. The pressing portion 104 may be located closer to the rear surface of the bottom chassis 100 than an end opposite to the one end at which the pressing portion 104 of the board mounting portion 101 is provided.

As one example, the board mounting portion 101 may include a first end in which the pressing portion 104 is located and a second end opposite to the first end in a direction in which the printed circuit board 110 is mounted to the bottom chassis 100. The second end of the board mounting portion 101 may extend to protrude from the rear surface of the bottom chassis 100. The first end of the board mounting portion 101 may be provided to be located closer to the rear surface of the bottom chassis 100 than the second end of the board mounting portion 101 such that the printed circuit board 110 is pressed in a direction toward close contact with the bottom chassis 100. The second end of the board mounting portion 101 may be located farther from the rear surface of the bottom chassis 100 than the first end in which the pressing portion 104 of the board mounting portion 101 is provided. The board mounting portion 101 may be provided to slope from the first end to the second end.

Referring to FIGS. 9 to 11, the board mounting portion 101 may form a mounting space 103 into which at least a portion of the printed circuit board 110 may be inserted. The mounting space 103 may be formed such that the insertion portion 111 of the printed circuit board 110 may be inserted thereinto. As the coupling portion 111 of the printed circuit board 110 is inserted into the mounting space 103, the printed circuit board 110 may be mounted to the bottom chassis 100. As an example, the board mounting portion 101 may be provided to form a portion that is open in the direction in which the printed circuit board 110 extends. For example, the board mounting portion 101 may include a portion that is open toward one side in the left-right direction to allow insertion of the coupling portion 111 of the printed circuit board 110.

The bottom chassis 100 may include a mounting guide 102 for guiding the mounting of the printed circuit board 110. The mounting guide 102 may be provided at one end of the board mounting portion 101. The mounting guide 102 may extend from the pressing portion 104 in a direction different from a direction in which the board mounting portion 101 extends The mounting guide 102 may guide the printed circuit board 110 to slide into the mounting space 103 when the printed circuit board 110 is mounted to the bottom chassis 100. For example, the mounting guide 102 may include an inclined surface inclined toward the mounting space 103 in a direction in which the printed circuit board 110 is inserted into the board mounting portion 101. The mounting guide 102 may extend in a direction different from a direction in the board mounting portion 101 extends.

The printed circuit board 110 may include a coupling portion 111 such that the printed circuit board 110 is mounted to the bottom chassis 100. The coupling portion 111 may be provided in a number corresponding to the number of board mounting portions 101. For example, referring to FIG. 5, four board mounting portions 101 are provided for a single printed circuit board 110, and the printed circuit board 110 may include four coupling portions 111. The coupling portion 111 may be inserted and fixed into the mounting space 103 formed by the board mounting portion 101 of the bottom chassis 100.

The printed circuit board 110 may include a grounding portion 112 such that a grounding area with the bottom chassis 100 is increased. The grounding portion 112 may be provided on the coupling portion 111. The grounding portion 112 may be provided on a surface of the coupling portion 111 that contacts the board mounting portion 101 while the coupling portion 111 is coupled to the board mounting portion 101. The grounding portion 112 may protrude from one surface of the coupling portion 111.

The grounding portion 112 may include a plurality of protrusions 112a. For example, the grounding portion 112 may be provided as a plurality of protrusions 112a arranged in a lattice pattern. For example, the grounding portion 112 may be provided in an embossed shape on one surface of the coupling portion 111. The number and/or shape of the plurality of protrusions 112a of the grounding portion 112 are not limited to those shown in FIG. 8, and may be variously implemented. As one example, the plurality of protrusions 112a of the grounding portion 112 may be provided with the same size.

The grounding portion 112 may include a material deformable when pressed by the bottom chassis 100. The grounding portion 112 may include a material deformable when pressed by the board mounting portion 101. The grounding portion 112 of the printed circuit board 110 may include a material more flexible than the bottom chassis 100. The grounding portion 112 may include a material more flexible than the board mounting portion 101. The grounding portion 112 may include a material having a lower strength than the bottom chassis 100.

The grounding portion 112 of the printed circuit board 110 may include a material different from the coupling portion 111 of the printed circuit board 110. The grounding portion 112 may include a material more flexible than the coupling portion 111. The grounding portion 112 may include a material having a lower strength than the coupling portion 111. For example, the grounding portion 112 may include lead. As one example, the grounding portion 112 may be formed during a soldering process of the printed circuit board 110. For example, the grounding portion 112 may be formed by soldering to the coupling portion 111 of the printed circuit board 110. Accordingly, the display device 1 according to an embodiment of the disclosure has a benefit of not requiring a separate process for forming the grounding portion 112.

The printed circuit board 110 may include a passing portion 113 through which the board mounting portion 101 of the bottom chassis 100 may pass. The board mounting portion 101 may be inserted into the passing portion 113. The passing portion 113 may be formed to pass through the printed circuit board 110. In a state in which the board mounting portion 101 has passed through the passing portion 113, the coupling portion 111 may be inserted by sliding into the mounting space 103.

The bottom chassis 100 and the printed circuit board 110 may be configured such that, while the board mounting portion 101 is inserted into the passing portion 113, the coupling portion 111 is accommodated in the mounting space 103 formed by the board mounting portion 101 as the printed circuit board 110 slides relative to the bottom chassis 100.

In the display device 1 according to an embodiment of the disclosure, the grounding area, in which the printed circuit board 110 and the bottom chassis 100 are grounded, is increased by the grounding portion 112, and thus static electricity applied to the printed circuit board 110 may be rapidly discharged, thereby improving electromagnetic susceptibility (EMS), and accordingly, the lifespan of the display device 1 may be increased. In addition, since the display device 1 according to an embodiment of the disclosure may improve EMS by the grounding portion 112, the use of additional components for EMS improvement may be minimized, thus reducing manufacturing costs.

In the display device 1 according to an embodiment of the disclosure, the grounding area, in which the printed circuit board 110 and the bottom chassis 100 are grounded, is increased by the grounding portion 112, and thus electromagnetic interference (EMI) may be reduced. In addition, since the display device 1 according to an embodiment of the disclosure may reduce EMI by the grounding portion 112, the use of additional components for EMI reduction may be minimized, thus reducing manufacturing costs.

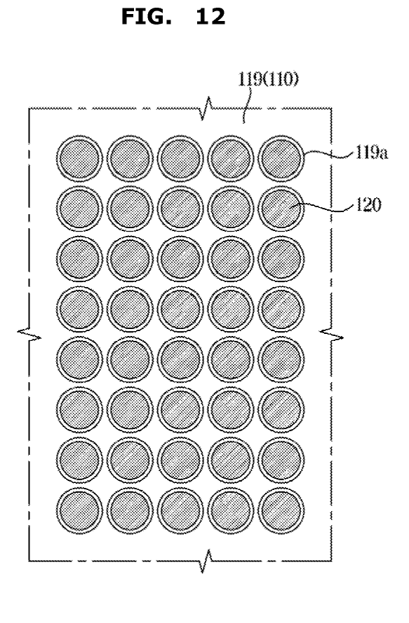

FIG. 12 illustrates a state in which a solder paste is applied to a printed circuit board of a display device according to an embodiment of the disclosure.

Referring to FIG. 12, in the display device 1 according to an embodiment of the disclosure, a solder paste 120 may be applied in the same size onto a solder mask 119 of the printed circuit board 110 in order to form a plurality of protrusions 112a of the grounding portion 112 in the same size on the printed circuit board 110. The solder paste 120 may be applied in the same amount onto the solder mask 119 of the printed circuit board 110. The solder mask 119 may be provided with a marking portion 119a for the solder paste 120. For example, the solder paste 120 may be applied onto the solder mask 119 while a metal mask is placed on the printed circuit board 110, through holes in the metal mask. By forming the holes of the metal mask in the same size, the solder paste 120 may be applied in the same size on the solder mask 119. The solder paste 120 applied onto the solder mask 119 may form the plurality of protrusions 112a of the grounding portion 112 when heated. For example, the solder paste 120 may be in the form of a paste made by mixing lead and flux particles.

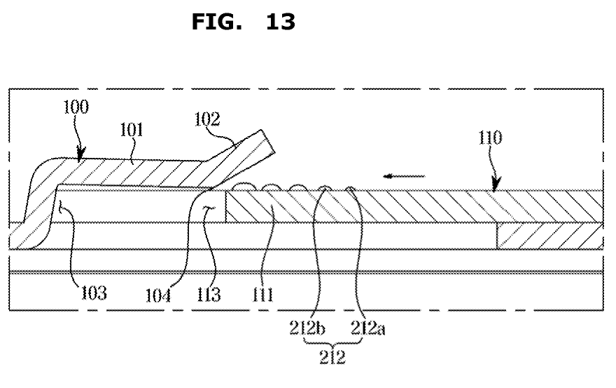

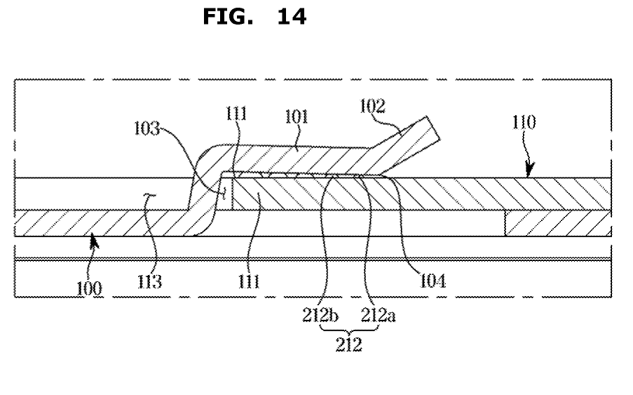

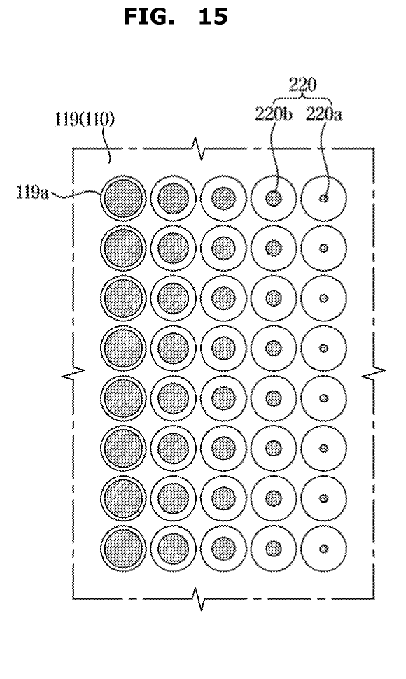

FIG. 13 illustrates an enlarged cross sectional view of a portion of a display device before a printed circuit board is mounted to a bottom chassis according to an embodiment of the disclosure. FIG. 14 illustrates an enlarged cross sectional view of a portion of a display device after a printed circuit board is mounted to a bottom chassis according to an embodiment of the disclosure. FIG. 15 illustrates a state in which a solder paste is applied to a printed circuit board of a display device according to an embodiment of the disclosure.

Referring to FIGS. 13 to 15, a grounding portion 212 of a display device 1 according to an embodiment of the disclosure will be described. In describing the grounding portion 212 shown in FIGS. 13 to 15, the same reference numerals are given to the same components as the configuration of the display device 1 shown in FIGS. 1 to 12, and detailed descriptions thereof will be omitted.

Referring to FIGS. 13 and 14, the grounding portion 212 according to an embodiment of the disclosure may include a plurality of protrusions 212a and 212b having different sizes. The plurality of protrusions 212a and 212b of the grounding portion 212 may be provided such that, while the coupling portion 111 is coupled to the board mounting portion 101, the size of the protrusions 212a and 212b increases with distance from the pressing portion 104.

As one example, the grounding portion 212 may include a first protrusion 212a that is pressed by the pressing portion 104 while the coupling portion 111 is coupled to the board mounting portion 101, and a second protrusion 212b that is spaced apart from the first protrusion 212a in a direction in which the printed circuit board 110 is mounted to the bottom chassis 100 and has a larger size than the first protrusion 212a.

Referring to FIG. 15, in the display device 1 according to an embodiment of the disclosure, a solder paste 220 may be applied in different sizes onto a solder mask 119 of the printed circuit board 110 in order to form a plurality of protrusions 212a and 212b of the grounding portion 212 in different sizes on the printed circuit board 110. The solder paste 220 may be applied in different amounts onto the solder mask 119 of the printed circuit board 110. The solder mask 119 may be provided with a marking portion 119a for the solder paste 220. For example, the solder paste 220 may be applied onto the solder mask 119 while a metal mask is placed on the printed circuit board 110, through holes in the metal mask. By forming the holes of the metal mask in different sizes, the solder paste 220 may be applied in different sizes onto the solder mask 119. The solder paste 220 applied onto the solder mask 119 may form the plurality of protrusions 212a and 212b of the grounding portion 212 when heated. For example, the solder paste 220 may be in the form of a paste made by mixing lead and flux particles

Referring to FIGS. 12 and 15, in the display device 1 according to an embodiment of the disclosure, the amount of solder paste 120, 220 to be applied may be adjusted by adjusting the size of the holes of the metal mask without changing the solder mask 119 of the printed circuit board 110, and accordingly, the size of the grounding portion 112, 212 may be adjusted.

A display device according to an embodiment includes a display panel, a chassis covering at least one side of the display panel, the chassis including a board mounting portion; and a printed circuit board detachably mountable to the chassis. The printed circuit board includes a coupling portion couplable to the board mounting portion, and a grounding portion protruding from a surface of the coupling portion. The printed circuit board and the chassis are configured such that, with the coupling portion coupled to the board mounting portion, the grounding portion is in contact with the board mounting portion so as to ground the printed circuit board to the chassis.

The grounding portion may include a material configured such that, with the coupling portion coupled to the board mounting portion, the board mounting portion presses and thereby deforms the material.

The board mounting portion may include a pressing portion configured such that, with the coupling portion coupled to the board mounting portion, the pressing portion presses and thereby deforms the material.

The grounding portion may include a first protrusion, and a second protrusion spaced apart from the first protrusion in a direction, in which the printed circuit board is mounted to the bottom chassis, and having a size larger than the first protrusion. The grounding portion and the board mounting portion may be configured such that, as the coupling portion is coupled to the board mounting portion, the pressing portion presses the second protrusion then presses the first protrusion

The board mounting portion may include a first end including the pressing portion, and a second end opposite to the first end. The second end may protrude from a rear surface of the chassis. The first end may be closer to the rear surface of the chassis than the second end, and is configured such that, with the coupling portion coupled to the board mounting portion, the printed circuit board is pressed toward the chassis by the first end.

The board mounting portion may include a mounting guide extending from the pressing portion in a direction away from a rear surface of the chassis. The mounting guide may be configured such that, as the coupling portion is coupled to the board mounting portion, movement of the coupling portion is guided by the mounting guide.

The grounding portion may include a first protrusion and a second protrusion spaced apart from the first protrusion. A size of the first protrusion may be equal to a size of the second protrusion.

The grounding portion may include a plurality of protrusions arranged in a grid pattern.

The grounding portion may include a material that is more flexible than a material of the board mounting portion.

The grounding portion may include lead.

The grounding portion may be soldered to the coupling portion.

The printed circuit board may include a passing portion through which the board mounting portion is passable. The board mounting portion may include a mounting space into which at least a portion of the coupling portion is accommodatable. The chassis and the printed circuit board may be configured such that, with the board mounting portion passes through the passing portion and the printed circuit board slid relative to the chassis toward the board mounting portion, the portion of the coupling portion is accommodated in a mounting space.

The board mounting portion may include a portion that is open in a direction in which the printed circuit board extends.

The display panel may be on a first side of the chassis. The printed circuit board may be on a second side of the chassis opposite to the first side.

An electronic device according to an embodiment includes a chassis including a board mounting portion, and a printed circuit board detachably mountable to the bottom chassis. The printed circuit board includes a coupling portion couplable to the board mounting portion, and a grounding portion protruding from a surface of the coupling portion and including a deformable material. The printed circuit board and the board mounting portion are configured such that, with the coupling portion coupled to the board mounting portion, the deformable material is pressed and thereby deformed by the board mounting portion, the board mounting portion contacts the deformable material so as to ground the printed circuit board to the chassis.

The grounding portion may include a first protrusion and a second protrusion that is spaced apart from the first protrusion and provided to have the same size as the first protrusion.

The grounding portion may include: a first protrusion pressed by the pressing portion while the coupling portion is coupled to the board mounting portion; and a second protrusion spaced apart from the first protrusion in a direction, in which the printed circuit board is mounted to the bottom chassis, and having a size larger than the first protrusion.

The board mounting portion may include a pressing portion configured to press the coupling portion in a direction in which the printed circuit board comes into close contact with the bottom chassis. The board mounting portion may include a first end at which the pressing portion is located and a second end opposite to the first end in a direction in which the printed circuit board is mounted to the bottom chassis. The second end may extend to protrude from a rear surface of the bottom chassis. The first end may be positioned closer to the rear surface of the bottom chassis than the second end such that the printed circuit board is pressed in a direction toward close contact with the bottom chassis.

The grounding portion may include lead.

The bottom chassis may include a mounting guide provided at one end of the board mounting portion to guide mounting of the coupling portion.

According to the spirit of the disclosure, the display device and the electronic device may include a grounding portion provided on the printed circuit board, thereby improving electromagnetic susceptibility (EMS).

According to the spirit of the disclosure, the display device and the electronic device may include a grounding portion provided on the printed circuit board, thereby reducing electromagnetic interference (EMI).

The effects of the disclosure are not limited to the effects described above, and other effects that are not described will be clearly understood by those skilled in the art from the above detailed description.

Although the disclosure has been shown and described in relation to specific embodiments, it would be appreciated by those skilled in the art that changes and modifications may be made in these embodiments without departing from the principles and scope of the disclosure, the scope of which is defined in the claims and their equivalents.

1. A display device comprising:
a display panel;
a chassis covering at least one side of the display panel, the chassis including a board mounting portion; and
a printed circuit board including:
a coupling portion couplable to the board mounting portion, and
a grounding portion protruding from a surface of the coupling portion,
wherein the printed circuit board and the chassis are configured such that, with the coupling portion coupled to the board mounting portion, the grounding portion is in contact with the board mounting portion so as to ground the printed circuit board to the chassis, and the printed circuit board is mounted to the chassis.

2. The display device of claim 1, wherein the grounding portion includes a material configured such that, with the coupling portion coupled to the board mounting portion, the board mounting portion presses and thereby deforms the material.

3. The display device of claim 2, wherein the board mounting portion includes a pressing portion configured such that, with the coupling portion coupled to the board mounting portion, the pressing portion presses and thereby deforms the material.

4. The display device of claim 3, wherein
the grounding portion includes:
a first protrusion, and
a second protrusion spaced apart from the first protrusion in a direction, in which the printed circuit board is mounted to the chassis, and having a size larger than the first protrusion, and
the grounding portion and the board mounting portion are configured such that, as the coupling portion is coupled to the board mounting portion, the pressing portion presses the second protrusion then presses the first protrusion.

5. The display device of claim 3, wherein
the board mounting portion includes:
a first end including the pressing portion, and
a second end opposite to the first end,
the second end protrudes from a rear surface of the chassis, and
the first end is closer to the rear surface of the chassis than the second end, and is configured such that, with the coupling portion coupled to the board mounting portion, the printed circuit board is pressed toward the chassis by the first end.

6. The display device of claim 3, wherein the board mounting portion includes a mounting guide extending from the pressing portion in a direction away from a rear surface of the chassis, and the mounting guide is configured such that, as the coupling portion is coupled to the board mounting portion, movement of the coupling portion is guided by the mounting guide.

7. The display device of claim 1, wherein
the grounding portion includes:
a first protrusion, and
a second protrusion spaced apart from the first protrusion, and
a size of the first protrusion is equal to a size of the second protrusion.

8. The display device of claim 1, wherein the grounding portion includes a plurality of protrusions arranged in a grid pattern.

9. The display device of claim 1, wherein the grounding portion includes a material that is more flexible than a material of the board mounting portion.

10. The display device of claim 1, wherein the grounding portion includes lead.

11. The display device of claim 1, wherein the grounding portion is soldered to the coupling portion.

12. The display device of claim 1, wherein
the printed circuit board includes a passing portion through which the board mounting portion is passable,
the board mounting portion includes a mounting space into which at least a portion of the coupling portion is accommodatable, and
the chassis and the printed circuit board are configured such that, with the board mounting portion passed through the passing portion and the printed circuit board slid relative to the chassis toward the board mounting portion, the portion of the coupling portion is accommodated in a mounting space.

13. The display device of claim 1, wherein the board mounting portion includes a portion that is open in a direction in which the printed circuit board extends.

14. The display device of claim 1, wherein
the display panel is on a first side of the chassis, and
the printed circuit board is on a second side of the chassis opposite to the first side.

15. An electronic device comprising:
a chassis including a board mounting portion; and
a printed circuit board including:
a coupling portion couplable to the board mounting portion, and
a grounding portion protruding from a surface of the coupling portion and including a deformable material,
wherein the printed circuit board and the board mounting portion are configured such that, with the coupling portion coupled to the board mounting portion, the deformable material is pressed and thereby deformed by the board mounting portion, the board mounting portion contacts the deformable material so as to ground the printed circuit board to the chassis, and the printed circuit board is mounted to the chassis.
